(19) United States
(12) Patent Application Publication
(10) Pub. No.: US 2013/0307014 A1
(43) Pub. Date: Nov. 21, 2013

(54) SEMICONDUCTOR LIGHT EMITTING DEVICE

(71) Applicants: Mami Yamamoto, Fukuoka-ken (JP); Kazuhiro Inoue, Fukuoka-ken (JP); Yasunori Nagahata, Fukuoka-ken (JP); Teruo Takeuchi, Fukuoka-ken (JP); Hidenori Egoshi, Fukuoka-ken (JP)

(72) Inventors: Mami Yamamoto, Fukuoka-ken (JP); Kazuhiro Inoue, Fukuoka-ken (JP); Yasunori Nagahata, Fukuoka-ken (JP); Teruo Takeuchi, Fukuoka-ken (JP); Hidenori Egoshi, Fukuoka-ken (JP)

(73) Assignee: Kabushiki Kaisha Toshiba, Tokyo (JP)

(21) Appl. No.: 13/614,779

(22) Filed: Sep. 13, 2012

(30) Foreign Application Priority Data
May 16, 2012 (JP) 2012-112747

(51) Int. Cl. H01L 33/52

(52) U.S. Cl. 257/99; 257/E33.059

(57) ABSTRACT

According to an embodiment, a semiconductor light emitting device includes a insulating base and a semiconductor light emitting element and resin. The insulating base includes a first face, a second face opposite to the first face, and a side face connecting to the first face and the second face, a recess portion being provided on the side face extending from the first face to the second face. The insulating base also includes a first metal layer blocking an opening of the recess portion, a second metal layer on an inner face of the recess portion, and a third metal layer on the second face, the third metal being electrically connected to the first metal layer via the second metal layer. A semiconductor light emitting element is fixed on the first face; and resin covers the first face and seals the semiconductor light emitting element.

### CROSS-REFERENCE TO RELATED APPLICATIONS

This application is based upon and claims the benefit of priority from Japanese Patent Application No. 2012-112747, filed on May 16, 2012; the entire contents of which are incorporated herein by reference.

### FIELD

Embodiments are related generally to a semiconductor light emitting device.

### BACKGROUND

The semiconductor light emitting device are going to be widely used as small-sized and easily handled light source, which includes a semiconductor light emitting element and a fluorescent substance, and emits visible light such as white light or light in other wavelength bands. For example, most packages that house semiconductor light emitting elements have a resin body formed using a special metal mold and leads extending from the resin body. A plurality of resin bodies are formed on a single lead frame sheet and then, each individual semiconductor light emitting device is manufactured by bending and cutting their respective leads.

Thus, a space occupied by the leads that extend from the resin bodies restricts the number of semiconductor devices made from a single lead frame, thereby limiting the improvement of productivity and the reduction of cost. In addition, the cost of the special metal molds may occupy a large portion of the manufacturing cost. Therefore, it is necessary for the semiconductor light emitting device to have the package suitable for increasing the productivity and reducing the manufacturing cost.

### BRIEF DESCRIPTION OF THE DRAWINGS

FIGS. 1A and 1B are schematic views illustrating a semiconductor light emitting device according to a first embodiment;

FIG. 2 is a flowchart illustrating a manufacturing process of the semiconductor light emitting device according to the first embodiment;

FIGS. 3A and 3B are schematic views illustrating a substrate used for the semiconductor light emitting device according, to the first embodiment;

FIGS. 4A to 4D are schematic cross-sectional views illustrating a manufacturing process of the substrate used for the semiconductor light emitting device according to the first embodiment;

FIGS. 5A to 6B are schematic views illustrating the manufacturing process of the semiconductor light emitting device according to the first embodiment;

FIGS. 7A to 7C are schematic views illustrating substrates used for a semiconductor device according to a variation of the first embodiment;

FIGS. 8A and 8B are schematic cross-sectional views illustrating a mounting process of the semiconductor light emitting device according to the first embodiment;

FIGS. 9A and 9B are schematic views illustrating a semiconductor light emitting device according to a second embodiment;

FIGS. 10A and 10B are schematic views illustrating a semiconductor light emitting device according to a third embodiment;

FIGS. 11A and 11B are schematic views illustrating a semiconductor light emitting device according to a variation of the third embodiment;

FIGS. 12A and 12B are schematic views illustrating a semiconductor light emitting device according to a fourth embodiment;

FIGS. 13A and 13B are schematic views illustrating a semiconductor light emitting device according to a fifth embodiment;

FIGS. 14A and 14B are schematic views illustrating a semiconductor light emitting device according to a sixth embodiment;

FIGS. 15A and 15B are schematic views illustrating a semiconductor light emitting device according to a seventh embodiment;

FIGS. 16A and 16B are schematic views illustrating a semiconductor light emitting device according to a variation of the seventh embodiment; and

FIGS. 17A and 17B are schematic views illustrating a semiconductor light emitting device according to an eighth embodiment.

### DETAILED DESCRIPTION

According to an embodiment, a semiconductor light emitting device includes an insulating base and a semiconductor light emitting element and resin. The insulating base includes a first face, a second face on a side opposite to the first face, and a side face connecting to the first face and the second face, a recess portion being provided on the side face extending from the first face to the second face. The insulating base also includes a first metal layer provided on the first face and blocking an opening of the recess portion, a second metal layer provided on an inner face of the recess portion, and a third metal layer provided on the second face, the third metal being electrically connected to the first metal layer via the second metal layer. A semiconductor light emitting element is fixed on the first face; and resin covers the first face and seals the semiconductor light emitting element, the resin transmitting at least part of light emitted from the semiconductor light emitting element.

Embodiments of the invention will now be described with referring to the drawings. Note that like elements in the drawings are denoted with like numerals, and detailed descriptions thereof are appropriately omitted while describing different elements.

### First Embodiment

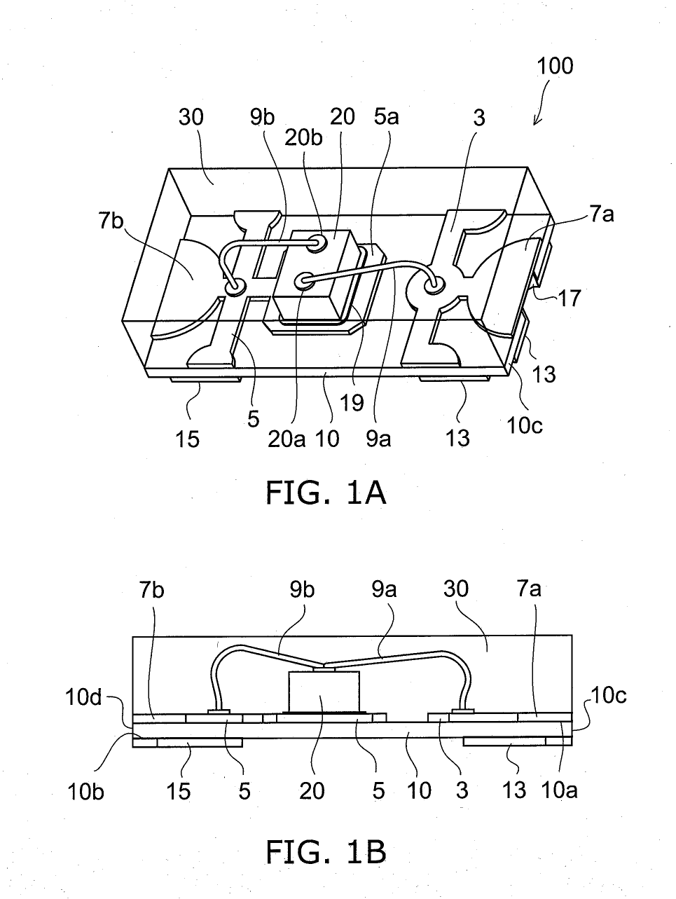

FIGS. 1A and 1B are schematic views illustrating a semiconductor light emitting device 100 according to a first embodiment. FIG. 1A is a perspective view schematically illustrating an external view of the semiconductor light emitting device 100, and FIG. 1B is a schematic front view thereof.

The semiconductor light emitting device 100 includes an insulating base 10, a semiconductor light emitting element 20, and resin 30 that seals the semiconductor light emitting element 20. In other words, the semiconductor light emitting device 100 has a configuration in which the semiconductor light emitting element 20 is housed in a package that includes the base 10 and the resin 30.

The base 10 includes a first face 10a, a second face 10b on a side opposite the first face 10a, and a side face 10c that contacts the first face 10a and the second face 10b. The side face 10c of the base 10 is provided with a recess portion 17 that extends from the first face 10a to the second face 10b.

As illustrated in FIG. 1A, an electrode 3 (first pad electrode) and an electrode 5 (second pad electrode) are disposed on the first face 10a of the base 10. In addition, an outer electrode 7a (first metal layer), a mount bed 5a, and an outer electrode 7b (first metal layer) are provided on the first face 10a. The outer electrode 7a is connected to the electrode 3, and the mount bed 5a and the outer electrode 7b are connected to the electrode 5.

The outer electrode 7a is provided blocking an opening of the recess portion 17. A metal layer 33 (second metal layer), for example, is provided on an inner face of the recess portion 17 as described later. Also, the outer electrode 7b blocks an opening of a recess portion 17 provided on a side face 10d on a side opposite the side face 10c.

As illustrated in FIG. 1B, back side metal (third metal layer) 13 and 15 are provided on the second face 10b. The back side metal 13 is electrically connected to the outer electrode 7a via the recess portion 17 of the side face 10c. On the other hand, the back side metal 15 is electrically connected to the outer electrode 7b via the recess portion 17 of the side face 10d. For example, the back side metal 13 may be connected to the outer electrode 7a via the metal layer 33 provided on the inner face of the recess portion 17, or it may be connected via metal embedded in the recess portion 17, or a so-called via plugging.

The semiconductor light emitting element 20 is fixed to the mount bed 5a provided on the first face 10a. For example, electrically conductive paste or adhesive can be used for fixing (die bonding) the semiconductor light emitting element 20.

The semiconductor light emitting element 20 is for example a light emitting diode (LED), having a p electrode and an n electrode on the upper surface. In the following, a first electrode 20a and a second electrode 20b are indicated, but in each case they may be a p electrode and an n electrode. The first electrode 20a is connected to the electrode 3 via a metal wire 9a, and the second electrode 20b is connected to the electrode 5 via a metal wire 9b. Also, the first electrode 20a is electrically connected to the back side metal 13 via the outer electrode 7a and the metal layer 33 of the recess portion 17 (first recess portion). The second electrode 20b is electrically connected to the back side metal 15 via the outer electrode 7b and the metal layer 33 of the recess portion 17 (second recess portion).

In addition, the semiconductor light emitting element 20 is sealed in the resin 30 that covers the first face 10a. The resin 30 is a transparent resin that transmits at least a portion of the light emitted by the semiconductor light emitting element 20. Also, the resin 30 may include a fluorescent substance that emits fluorescent light, which is excited by the light emitted from the semiconductor light emitting element 20. Also, as illustrated in FIGS. 1A and 1B, the resin 30 covers the whole first face 10a of the base 10.

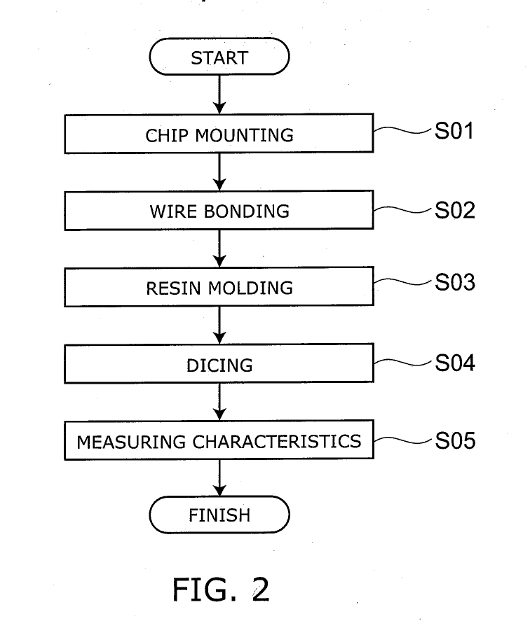

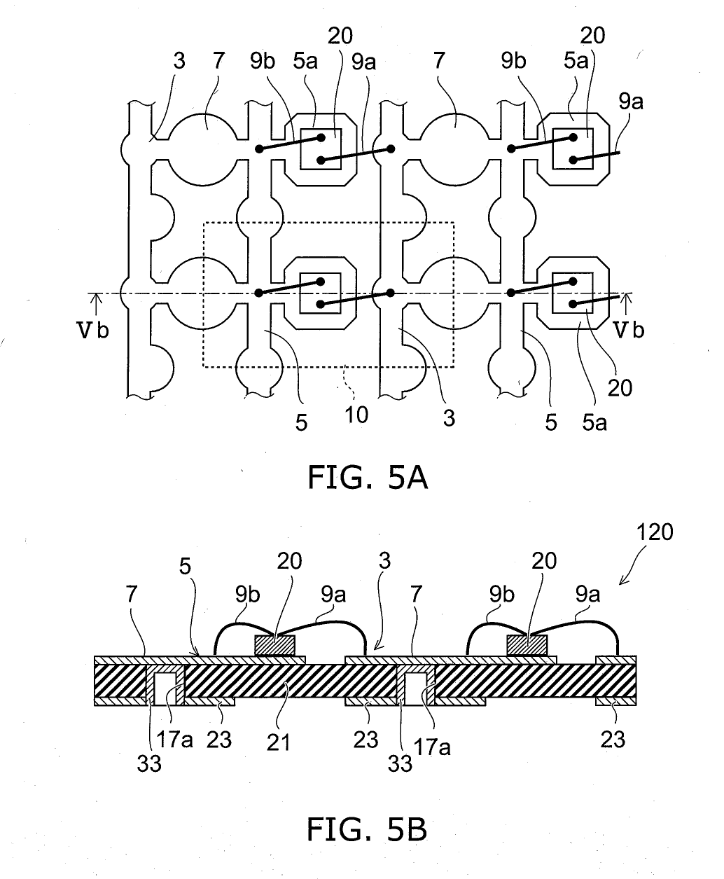

FIG. 2 is a flowchart illustrating the manufacturing process of the semiconductor light emitting device 100. First, a plurality of semiconductor light emitting elements 20 is mounted on a substrate (see FIG. 5), and fixed thereon (chip mounting: S01). Then, the metal wire 9a is bonded to the first electrode 20a and the electrode 3 so that they are electrically connected to each other. The metal wire 9b is bonded to the second electrode 20b and the electrode 5 so that they are electrically connected to each other (S02).

Next, the resin 30 is formed on the substrate, to seal the semiconductor light emitting elements 20 (S03). For example, the resin 30 is formed to have a uniform thickness on the substrate using a silicone resin. Then, the substrate on which the resin 30 has been formed is cut using, for example, a dicing blade, and each individual semiconductor light emitting device 100 is cut out therefrom (S04). Then, the characteristics of the semiconductor light emitting devices 100 are individually checked, whereby selecting ones that satisfy a predetermined specification (S05).

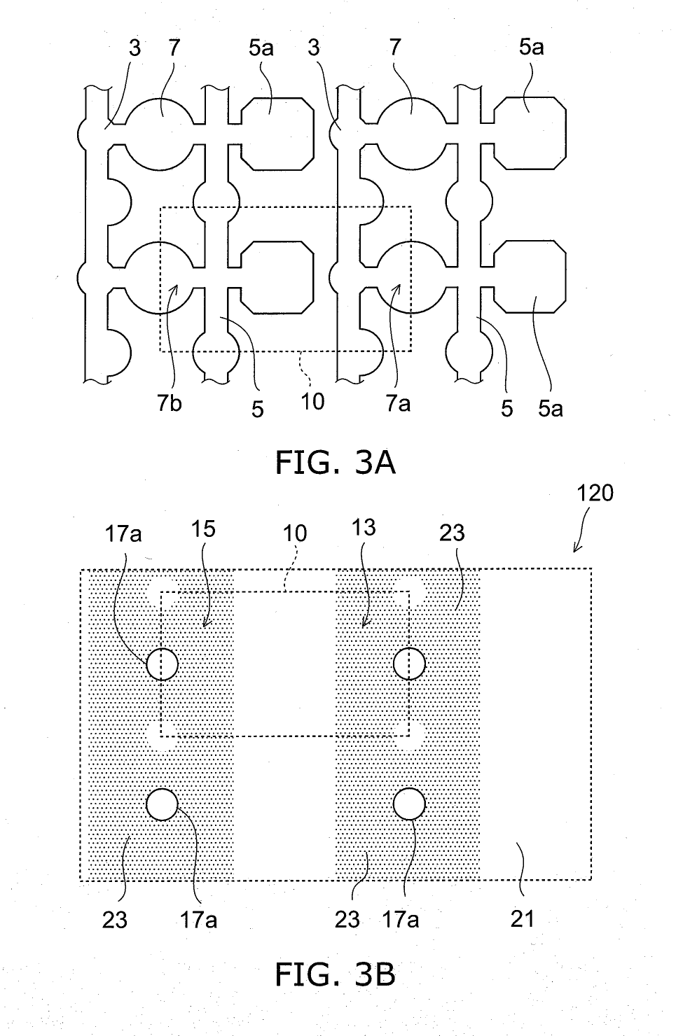

FIGS. 3A and 3B are schematic views illustrating a substrate 120 used in the semiconductor light emitting device according to the first embodiment. FIG. 3A is a plan view illustrating a surface side electrode pattern, and FIG. 3B is a plan view illustrating a backside metal pattern.

As illustrated in FIG. 3A, a pattern is provided in which the electrode 3 and the electrode 5 are connected via an electrode 7. The mount bed 5a is provided at a position on a side of the electrode 5 opposite to the electrode 7. On the other hand, a through hole 17a is provided on a back side illustrated in FIG. 3B, at a position corresponding to the center of the electrode 7, and a metal pattern 23 is provided around the through hole 17a.

The dotted lines illustrated in FIGS. 3A and 3B represent one base 10 that is cut out from the substrate 120 in the process S04 shown in FIG. 2. In other words, the electrode 7 is cut in the center to form the outer electrodes 7a and 7b. On the back face side, the through hole 17a is cut in the center, to form the recess portions 17 in the side faces 10c and 10d respectively. Also, the metal pattern 23 is cut into the back side metal 13 and 15.

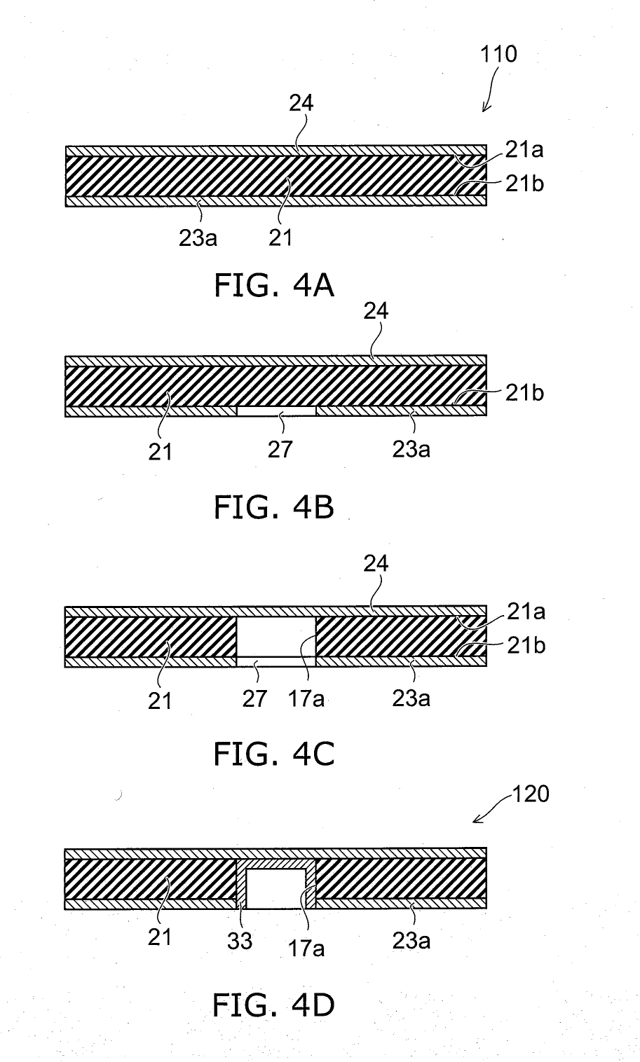

FIGS. 4A through 4D are schematic views illustrating the manufacturing process of the substrate 120. As illustrated in FIG. 4A, the substrate 120 is manufactured using an insulating body 21 with, for, example, metal layers 24 and 23a provided on a front surface 21a and a back surface 21b of the insulating body 21 respectively. The insulating body 21 is, for example, a polyimide film, to both surfaces of which copper foil is bonded as the metal layers 24 and 23a.

As illustrated in FIG. 4B, the metal layer 23a provided on the back surface 21b is selectively etched to form an aperture 27. Then, as illustrated in FIG. 4C, the through hole 17a that extends from the back surface 21b to the front surface 21a is formed in the insulating body 21. The through hole 17a is formed, for example, by selectively removing the insulating body 21 by irradiating it with laser light through the aperture 27. Also, the metal layer 24 on the front surface 21a side is not removed, but remains to block the aperture of the through hole 17a.

Next, as illustrated in FIG. 4D, the metal layer 33 is formed on the inner face of the through hole 17a. The metal layer 33 is a thin film made from, for example, gold (Au), silver (Ag), or palladium (Pd), and can be formed by an electroplating method or an electroless plating method. In this way, the metal layer 24 formed on the front surface 21a and the metal layer 23a formed on the back surface 21b are electrically connected. Also, the metal layer 33 is formed on the inner face of the whole through hole 17a provided on the back surface 21b.

Then, the metal layer 24 on the front surface 21a is processed to the pattern illustrated in FIG. 3A, the metal layer 23a on the back surface 21b side is processed to the metal pattern 23 illustrated in FIG. 3B, and the substrate 120 is completed.

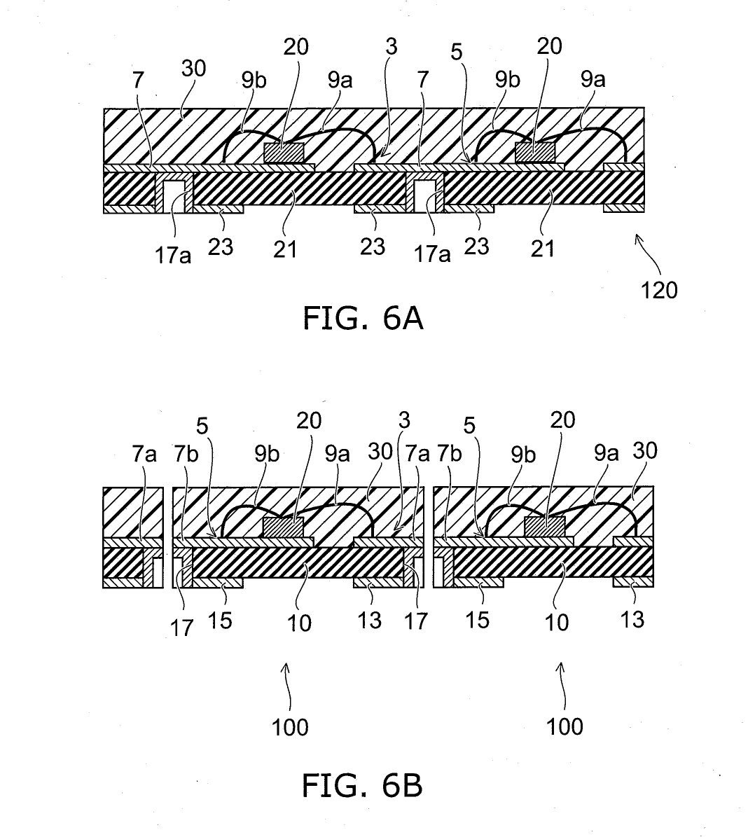

FIG. 5A through FIG. 6B are schematic views illustrating the manufacturing process of the semiconductor light emitting device 100. FIG. 5A is a plan view illustrating the surface of the substrate 120, and FIGS. 5B to 6B are sectional views along the line Vb-Vb in FIG. 5A.

FIG. 5A and FIG. 5B illustrate the substrate 120 on which the semiconductor light emitting elements 20 are mounted. Each of the semiconductor light emitting elements 20 is fixed to one of the plurality of mount beds 5a. Then, the electrode 3 and the electrode 5 are connected with the metal wires 9a and 9b. Then, as illustrated in FIG. 5B, the electrode 3 and the electrode 5 are electrically connected to the metal pattern 23 via the electrode 7 and the metal layer 33.

Next, as illustrated in FIG. 6A, the resin 30 is formed covering the surface of the substrate 120. The resin 30 may be formed as a resin layer with a uniform thickness using vacuum forming. In other words, it is not necessary to use a special metal mold in accordance with the shape of the package in each product, so it is possible to improve the productivity.

Next, the resin 30 and the substrate 120 are cut as illustrated in FIG. 6B, and each individual semiconductor light emitting device 100 is cut out therefrom. In this way, the substrate 120 is divided into the base 10, and the recess portions 17 are formed in the side faces of the base 10.

Since the semiconductor light emitting device 100 is cut out to the size of its package, there is no space for the leads extending from the package. Therefore, the whole substrate 120 is effectively utilized, and it is possible to increase the yield of semiconductor light emitting devices 100. Also, since the special metal mold is not used in the manufacturing process, it is possible to reduce the manufacturing cost.

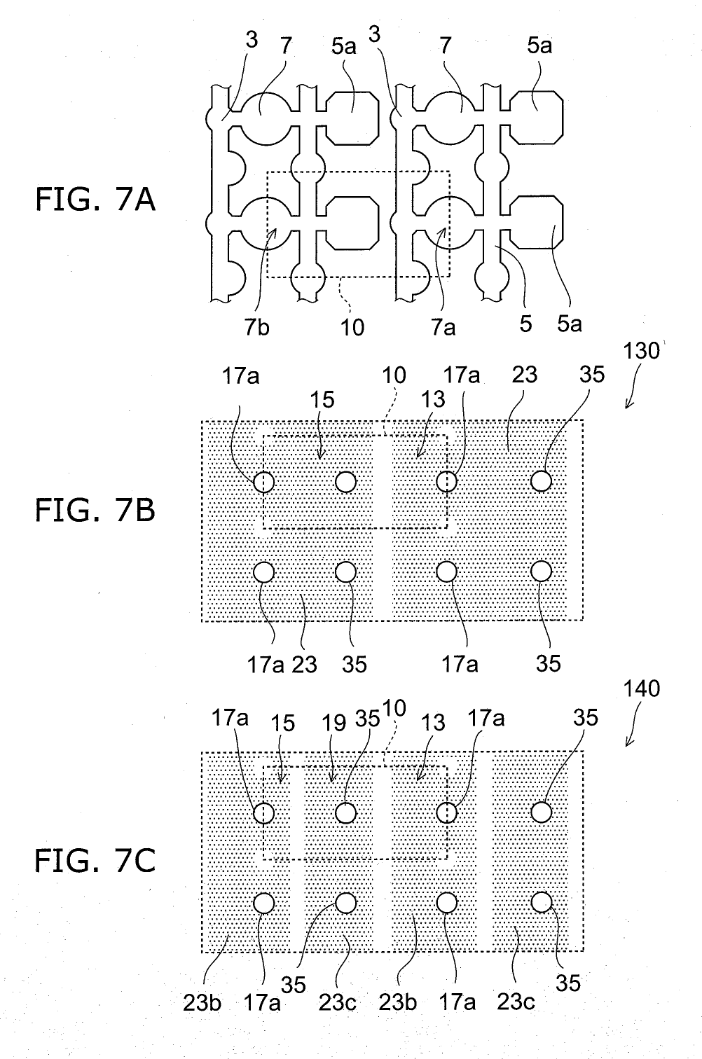

FIG. 7 is a schematic view illustrating substrates 130 and 140 used in a semiconductor device according to a variation of the first embodiment. FIG. 7A is a plan view illustrating the electrode pattern provided on the front surface of each substrate, and is the same as the pattern illustrated in FIG. 3A. FIG. 7B and FIG. 7C are plan views illustrating the back side of the substrates 130 and 140 respectively.

As illustrated in FIG. 7B, a through hole 35 is provided in the substrate 130 in addition to the through hole 17a. Also, the area of the metal pattern 23 is extended, and is provided around both the through hole 17a and the through hole 35. Also, the through hole 35 is provided at a position corresponding to the mount bed 5a (fourth metal layer) illustrated in FIG. 7A. The metal layer 33 (fifth metal layer) is provided on the inner face of the through hole 35, so the mount bed 5a and the metal pattern 23 are electrically connected. Also, it may be possible to embed the metal in the interior of the through hole 35.

As illustrated by the broken line in FIG. 7B, the base 10 cut out from the substrate 130 includes the backside metal 13 provided around the recess portion 17, and the backside metal 15 provided around the recess portion 17 and the through hole 35. Also, the backside metal 15 is electrically connected to the outer electrode 7b via the recess portion 17, and is also electrically connected to the mount bed 5a via the through hole 35.

In the substrate 140 illustrated in FIG. 7C, the metal pattern 23 illustrated in FIG. 7B is divided into a metal pattern 23b provided around the through hole 17a, and a metal pattern 23c provided around the through hole 35. Therefore, in the base 10 cut out from the substrate 140, the backside metal 13 connected to the outer electrode 7a via the recess portion 17, the backside metal 15 connected to the outer electrode 7b via the recess portion 17, and a back side metal 19 (sixth metal layer) connected to the mount bed 5a via the through hole 35 are provided.

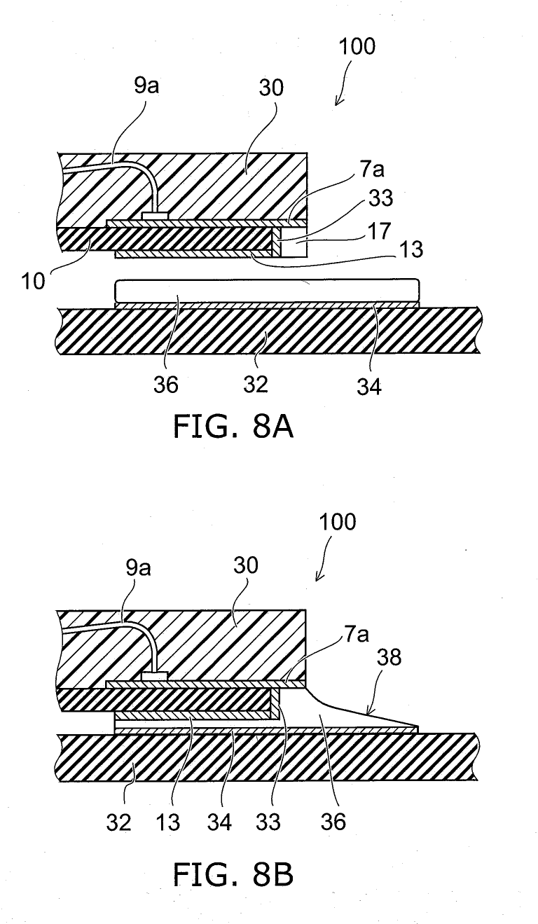

Next, the process of mounting the semiconductor light emitting device 100 is described with reference to FIGS. 8A and 8B. FIG. 8A is a schematic sectional view illustrating the semiconductor light emitting device 100 immediately before mounting on a substrate 32. FIG. 8B is a schematic sectional view illustrating the semiconductor light emitting device 100 immediately after mounting on the substrate 32.

As illustrated in FIG. 8A, the mounting substrate 32 has a land pattern 34 on its upper face, and solder cream 36 is applied to the surface of the land pattern 34. The semiconductor light emitting device 100 is placed on a predetermined position on the mounting substrate 32, and then is carried into a reflow oven while the backside metal 13 is in contact with the solder cream 36. In this process, the melted solder cream 36 spreads over the entire backside metal 13, and the semiconductor light emitting device 100 is fixed to the mounting substrate 32 after cooling down.

Also, the solder cream 36 climbs up along the surface of the metal layer 33 in the recess portion 17 and contacts the back face side of the outer electrode 7a, and forms a fillet 38 as illustrated in FIG. 8B. In this way, it is possible to inspect the wettability between the backside metal 13 and the solder cream 36 in visual inspection after mounting the semiconductor light emitting device 100. Also, when there is a fault on the semiconductor light emitting device 100 mounted on the mounting substrate 32, it is possible to replace the semiconductor light emitting device 100 by contacting and heating the fillet 38 with a soldering iron and melting the solder.

In other words, it was difficult to form fillets 38 using the semiconductor light emitting device having mounting pads on the back face side, and therefore, difficult to improve the reliability of the mounting substrate and to carry out its repair. In this embodiment, the recess portion 17 provided in the side face of the base 10 makes it easy to form the fillet 38 in the substrate, on which the semiconductor light emitting device 100 is mounted, and may improve the reliability and the reparability thereof.

### Second Embodiment

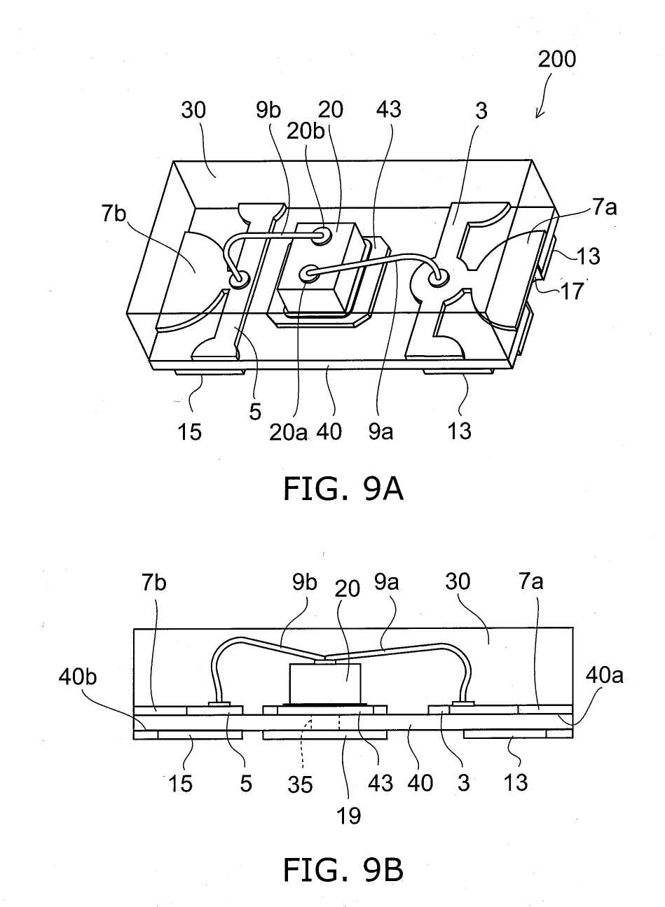

FIGS. 9A and 9B are schematic views illustrating a semiconductor light emitting device 200 according to a second embodiment. FIG. 9A is a perspective view schematically illustrating an external view of the semiconductor light emitting device 200, and FIG. 9B is a schematic front view thereof.

The semiconductor light emitting device 200 includes an insulating base 40, the semiconductor light emitting element 20, and resin 30 that seals the semiconductor light emitting element 20.

As illustrated in FIG. 9A, the electrode 3 and the electrode 5 are disposed on a first face 40a of the base 40. In addition, the outer electrode 7a, a mount bed 43, and the outer electrode 7b are provided on the first face 40a. In this embodiment, the mount bed 43 and the electrode 5 are separated from each other.

The first electrode 20a of the semiconductor light emitting element 20 that is fixed on the mount bed 5a is connected to the electrode 3 via the metal wire 9a, and the second electrode 20b is connected to the electrode 5 via the metal wire 9b. Also, the first electrode 20a is electrically connected to the backside metal 13 via the outer electrode 7a and the metal layer 33 of the recess portion 17. The second electrode 20b is electrically connected to the backside metal 15 via the outer electrode 7b and the metal layer 33 of the recess portion 17.

The backside metal 13, 15, and 19 are provided on a second face 40b of the base 40. The backside metal 19 is provided separated from the backside metal 13 and 15, and is connected to the mount bed 43 via the through hole 35 (see FIG. 7C). Therefore, the current that drives the semiconductor light emitting element 20 is supplied from the backside metal 13 and 15, and the heat of the semiconductor light emitting element 20 is dissipated from the backside metal 19 via the through hole 35. In other words, in the semiconductor light emitting device 200, it is possible to improve the heat dissipation by bringing the backside metal 19 into contact with a heat sink, enabling high output operation under driving with high current.

### Third Embodiment

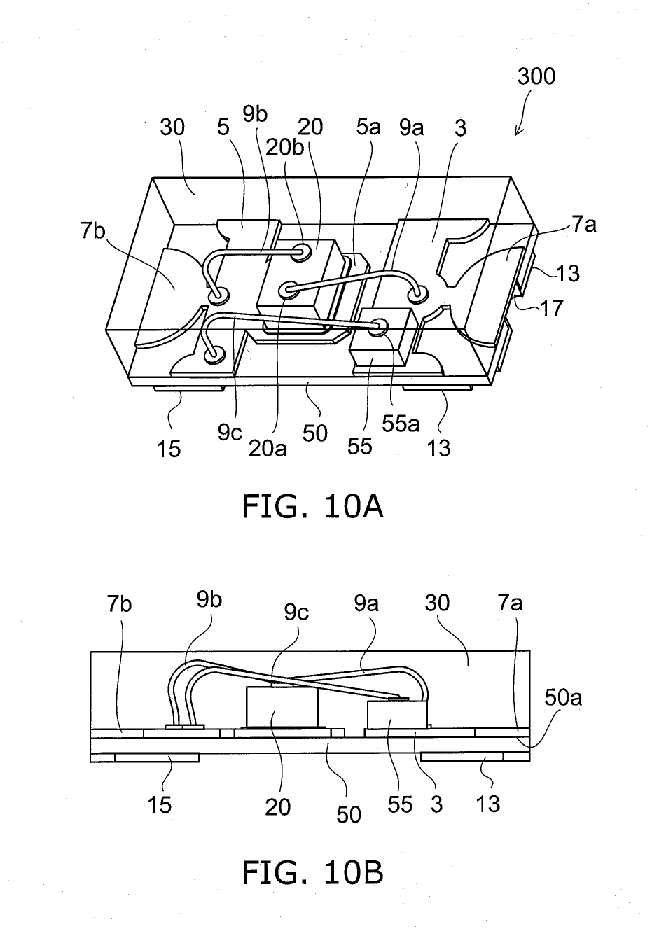

FIGS. 10A and 10B are schematic views of a semiconductor light emitting device 300 according to a third embodiment. FIG. 10A is a perspective view schematically illustrating an external view of the semiconductor light emitting device 300, and FIG. 10B is a schematic front view thereof.

The semiconductor light emitting device 300 includes an insulating base 50, the semiconductor light emitting element 20, a protective element 55, and resin 30 that seals the semiconductor light emitting element 20 and the protective element 55. The protective element 55 is, for example, a Zener diode, that suppresses excess current flowing through the semiconductor light emitting element 20.

As illustrated in FIG. 10A, the electrode 3 and the electrode 5 are disposed on a first face 50a of the base 50. In addition, the outer electrode 7a, the mount bed 5a, and the outer electrode 7b are provided on the first face 50a. The outer electrode 7a is connected to the electrode 3, and the mount bed 5a and the outer electrode 7b are connected to the electrode 5.

The first electrode 20a of the semiconductor light emitting element 20 fixed on the mount bed 5a is connected to the electrode 3 via the metal wire 9a, and the second electrode 20b is connected to the electrode 5 via the metal wire 9b. Also, the first electrode 20a is electrically connected to the backside metal 13 via the outer electrode 7a and the metal layer 33 of the recess portion 17. The second electrode 20b is electrically connected to the backside metal 15 via the outer electrode 7b and the metal layer 33 of the recess portion 17.

The protective element 55 is mounted on the electrode 3, and a metal wire 9c is connected between an electrode 55a on the upper surface of the protective element 55 and the electrode 5. The protective element 55 operates by current flowing between the electrode 55a on the upper surface and a lower surface electrode. Therefore, the lower surface electrode of the protective element 55 is electrically connected to the electrode 3. Thereby, the resistance of the semiconductor light emitting device 300 to high voltages is improved, so it is possible to prevent failure due to static electricity surges.

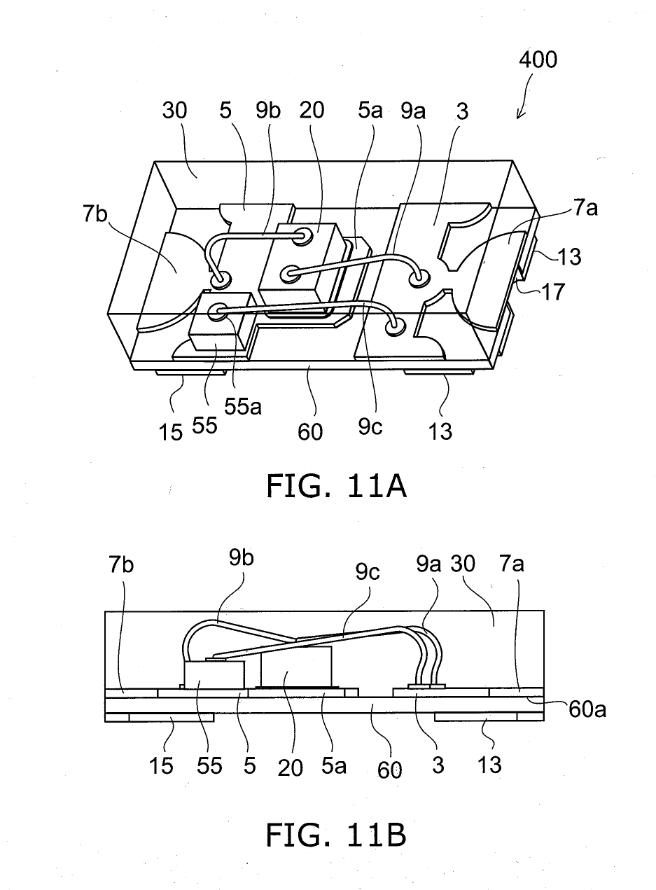

FIGS. 11A and 11B are schematic views illustrating a semiconductor light emitting device 400 according to a variation of the third embodiment. FIG. 11A is a perspective view schematically illustrating an external view of the semiconductor light emitting device 400, and FIG. 11B is a schematic front view thereof.

The semiconductor light emitting device 400 includes an insulating base 60, the semiconductor light emitting element 20, the protective element 55, and resin 30 that seals the semiconductor light emitting element 20 and the protective element 55.

As illustrated in FIG. 11A, the electrode 3 and the electrode 5 are disposed on a first face 60a of the base 60. In addition, the outer electrode 7a, the mount bed 5a, and the outer electrode 7b are provided on the first face 60a. The outer electrode 7a is connected to the electrode 3, and the mount bed 5a and the outer electrode 7b are connected to the electrode 5.

The first electrode 20a of the semiconductor light emitting element 20 fixed on the mount bed 5a is connected to the electrode 3 via the metal wire 9a, and the second electrode 20b is connected to the electrode 5 via the metal wire 9b. Also, the first electrode 20a is electrically connected to the backside metal 13 via the outer electrode 7a and the metal layer 33 of the recess portion 17. The second electrode 20b is electrically connected to the backside metal 15 via the outer electrode 7b and the metal layer 33 of the recess portion 17.

The protective element 55 is mounted on the electrode 5, and the metal wire 9c connects between the electrode 55a on the upper surface of the protective element 55 and the electrode 3. The protective element 55 operates by current flowing between the electrode 55a on the upper surface and a lower surface electrode. Therefore, the lower surface electrode of the protective element 55 is electrically connected to the electrode 5. Thereby, the resistance of the semiconductor light emitting device 400 to high voltages, for example, is improved, so it is possible to prevent failure due to static electricity surges.

### Fourth Embodiment

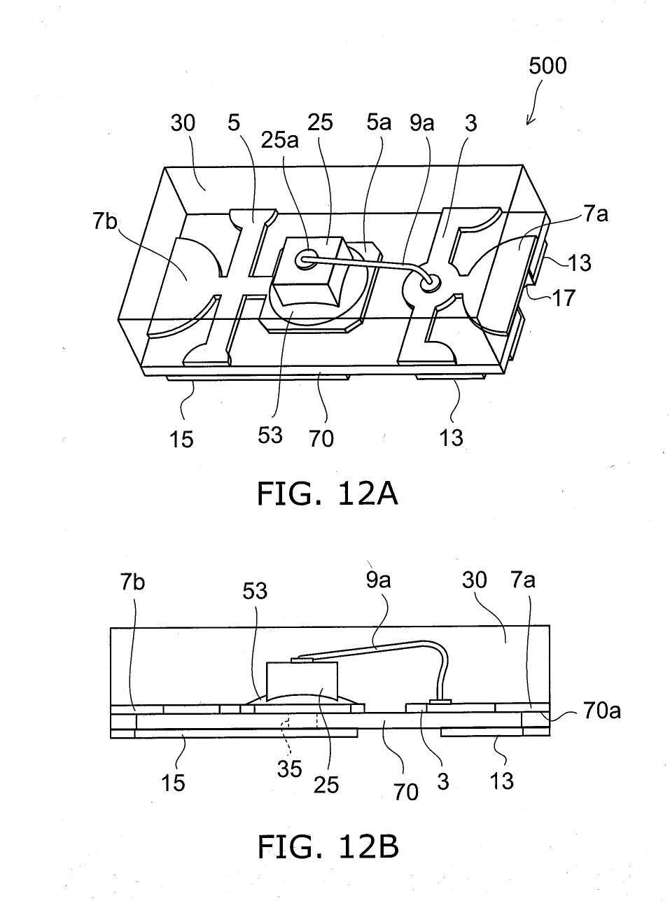

FIGS. 12A and 12B are schematic views of a semiconductor light emitting device 500 according to a fourth embodiment. FIG. 12A is a perspective view schematically illustrating an external view of the semiconductor light emitting device 500, and FIG. 12B is a schematic front view thereof.

The semiconductor light emitting device 500 includes an insulating base 70, a semiconductor light emitting element 25, and resin 30 that seals the semiconductor light emitting element 25. The semiconductor light emitting element 25 emits light when current is passed between an upper surface electrode 25a and a lower surface electrode.

As illustrated in FIG. 12A, the electrode 3 and the electrode 5 are disposed on a first face 70a of the base 70. In addition, the outer electrode 7a, the mount bed 5a, and the outer electrode 7b are provided on the first face 70a. The outer electrode 7a is connected to the electrode 3, and the mount bed 5a and the outer electrode 7b are connected to the electrode 5.

The semiconductor light emitting element 25 is fixed to the mount bed 5a with electrically conductive paste 53. In this way, the lower surface electrode is connected to the electrode 5 via the mount bed 5a. The upper surface electrode 25a of the semiconductor light emitting element 25 is connected to the electrode 3 via the metal wire 9a. Also, the upper surface electrode 25a is electrically connected to the backside metal 13 via the outer electrode 7a and the metal layer 33 of the recess portion 17.

As illustrated in FIG. 12B, the base 70 has the through hole 35 below the mount bed 5a, the mount bed 5a and the back side metal 15 are electrically connected via the metal layer 33 provided on the inner face of the through hole 35 (see FIG. 7B). Also, the electrode 5 is electrically connected to the backside metal 15 via the outer electrode 7b and the metal layer 33 of the recess portion 17. Therefore, a backside electrode of the semiconductor light emitting element 25 is electrically connected to the backside metal 15 by both the connection via the through hole 35 and the connection via the outer electrode 7b and the recess portion 17.

In addition, in this embodiment, the heat of the semiconductor light emitting element 25 can be dissipated via the through hole 35, enabling high current and high output operation.

### Fifth Embodiment

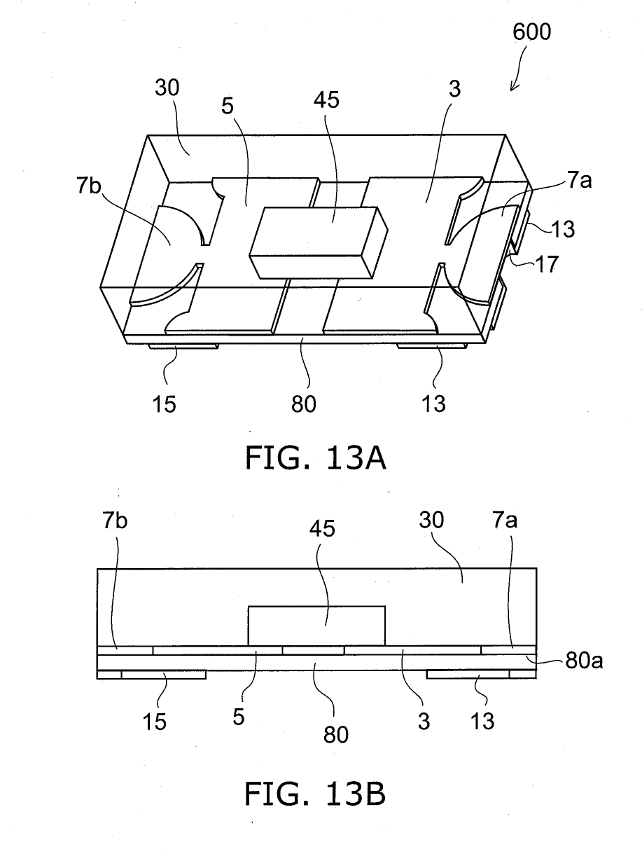

FIGS. 13A and 13B are schematic views of a semiconductor light emitting device 600 according to a fifth embodiment. FIG. 13A is a perspective view schematically illustrating an external view of the semiconductor light emitting device 600, and FIG. 13B is a schematic front view thereof.

The semiconductor light emitting device 600 includes an insulating base 80, a semiconductor light emitting element 45, and resin 30 that seals the semiconductor light emitting element 45.

The semiconductor light emitting element 45 has a flip-chip construction with the first electrode and the second electrode (not illustrated in the drawings) on the lower surface of the semiconductor light emitting element 45.

As illustrated in FIG. 13A, the electrode 3 and the electrode 5 are disposed on a first face 80a of the base 80. In addition, the outer electrode 7a and the outer electrode 7b are provided on the first face 80a. The outer electrode 7a is connected to the electrode 3, and the outer electrode 7b is connected to the electrode 5.

The semiconductor light emitting element 45 is flip-chip bonded to the electrode 3 and the electrode 5. For example, the semiconductor light emitting element 45 is fixed to the electrode 3 and the electrode 5 via solder balls or the like. In other words, the electrode 3 is connected to the first electrode via a solder ball, and the electrode 5 is connected to the second electrode via a solder ball. The first electrode is electrically connected to the backside metal 13 via the outer electrode 7a and the metal layer 33 of the recess portion 17, and the second electrode is electrically connected to the backside metal 15 via the outer electrode 7b and the metal layer 33 of the recess portion 17.

In this embodiment, there are no connections using metal wire, so the thickness of the resin 30 can be reduced. Therefore, the height of the package can be reduced.

### Sixth Embodiment

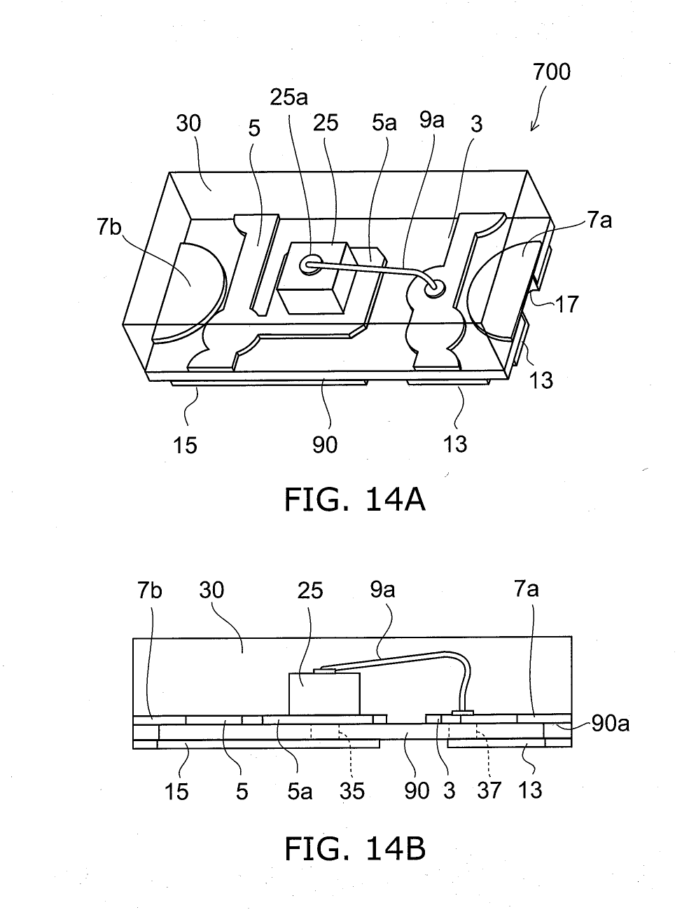

FIGS. 14A and 14B are schematic views of a semiconductor light emitting device 700 according to a sixth embodiment. FIG. 14A is a perspective view schematically illustrating an external view of the semiconductor light emitting device 700, and FIG. 14B is a schematic front view thereof.

The semiconductor light emitting device 700 includes an insulating base 90, the semiconductor light emitting element 25, and resin 30 that seals the semiconductor light emitting element 25. The semiconductor light emitting element 25 emits light when current is passed between an upper surface electrode 25a and a lower surface electrode.

As illustrated in FIG. 14A, the electrode 3 and the electrode 5 are disposed on a first face 90a of the base 90. In addition, the outer electrode 7a, the mount bed 5a, and the outer electrode 7b are provided on the first face 90a. In the embodiment, the outer electrode 7a is separated from the electrode 3, and the outer electrode 7b is separated from the electrode 5.

The semiconductor light emitting element 25 is fixed to the mount bed 5a with electrically conductive paste 53. In this way, the lower surface electrode is connected to the electrode 5 via the mount bed 5a. The upper surface electrode 25a of the semiconductor light emitting element 20 is connected to the electrode 3 via the metal wire 9a.

In the embodiment, the electrode 3 and the outer electrode 7a are separated, so there is no current path to the backside metal 13 via the outer electrode 7a and the recess portion 17. Also, the electrode 5 and the outer electrode 7b are separated, so there is no current path to the backside metal 15 via the outer electrode 7b and the recess portion 17. Therefore, the base 90 has the through hole 35 below the mount bed 5a as illustrated in FIG. 14B, and the mount bed 5a and the backside metal 15 are electrically connected via the metal layer 33 provided on the inner face of the through hole 35. Also, a through hole 37 is provided below the electrode 3, and the electrode 3 and the backside metal 13 are electrically connected via a metal layer 33 provided on the inner face of the through hole 37. In this way, the upper surface electrode 25a of the semiconductor light emitting element 25 and the backside metal 13 are electrically connected via the through hole 37. On the other hand, the lower surface electrode of the semiconductor light emitting element 25 is electrically connected to the backside metal 15 via the through hole 35.

In the embodiment, the outer electrode 7a and the electrode 3 are separated from each other, and the outer electrode 7b and the electrode 5 are separated from each other. As a result, the adhesion at the interface between the resin 30 and the first face 90a of the base 90 is improved, and it is possible to suppress a penetration of solder or flux. As a result, it is possible to prevent peeling of the metal wire 9a and degradation of the semiconductor light emitting element 25.

### Seventh Embodiment

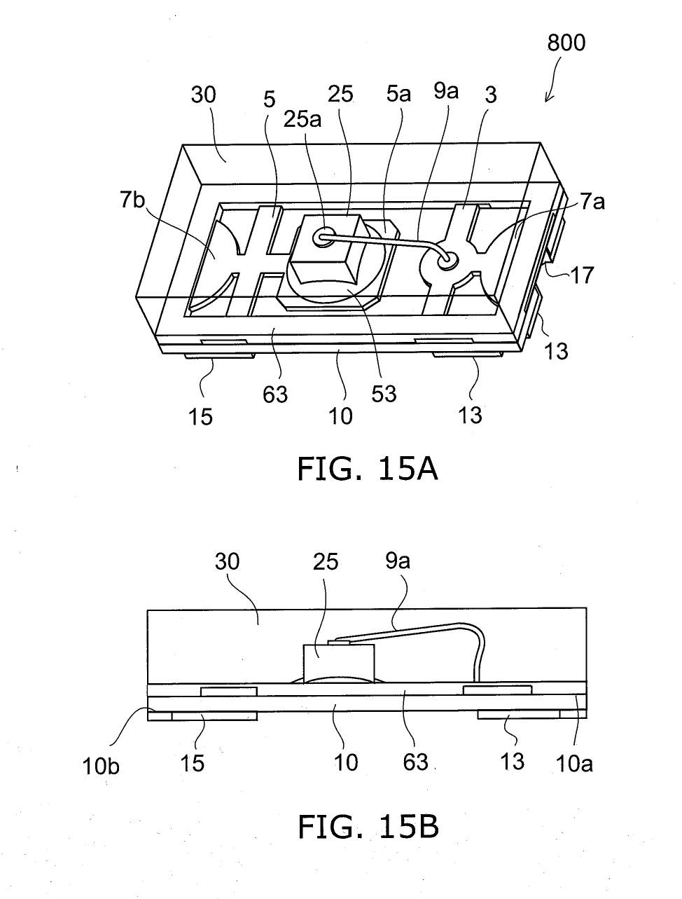

FIGS. 15A and 15B are schematic views of a semiconductor light emitting device 800 according to a seventh embodiment. FIG. 15A is a perspective view schematically illustrating an external view of the semiconductor light emitting device 800, and FIG. 15B is a schematic front view thereof.

The semiconductor light emitting device 800 includes the insulating base 10, the semiconductor light emitting element 25, and resin 30 that seals the semiconductor light emitting element 25. The semiconductor light emitting element 25 emits light when current is passed between an upper surface electrode 25a and a lower surface electrode 25.

In addition, in the embodiment, a resin layer 63 is provided between the first face 10a of the base 10 and the resin 30. The resin layer 63 is provided along the outer edge of the base 10, and has greater adhesion to the first face 10a than the resin 30.

The semiconductor light emitting element 25 is fixed to the mount bed 5a with electrically conductive paste 53. Also, the upper surface electrode 25a of the semiconductor light emitting element 25 is connected to the electrode 3 via the metal wire 9a. The electrode 3 is electrically connected to the backside metal 13 via the outer electrode 7a and the recess portion 17. On the other hand, the lower surface electrode of the semiconductor light emitting element 25 is electrically connected to the mount bed 5a via the electrically conductive paste 53. The mount bed 5a is electrically connected to the backside metal 15 via the electrode 5, the outer electrode 7b and the recess portion 17.

In the embodiment, adhesion is improved by interposing the resin layer 63 between the resin 30 and the base 10, so it is possible to suppress the penetration of solder or flux into the package.

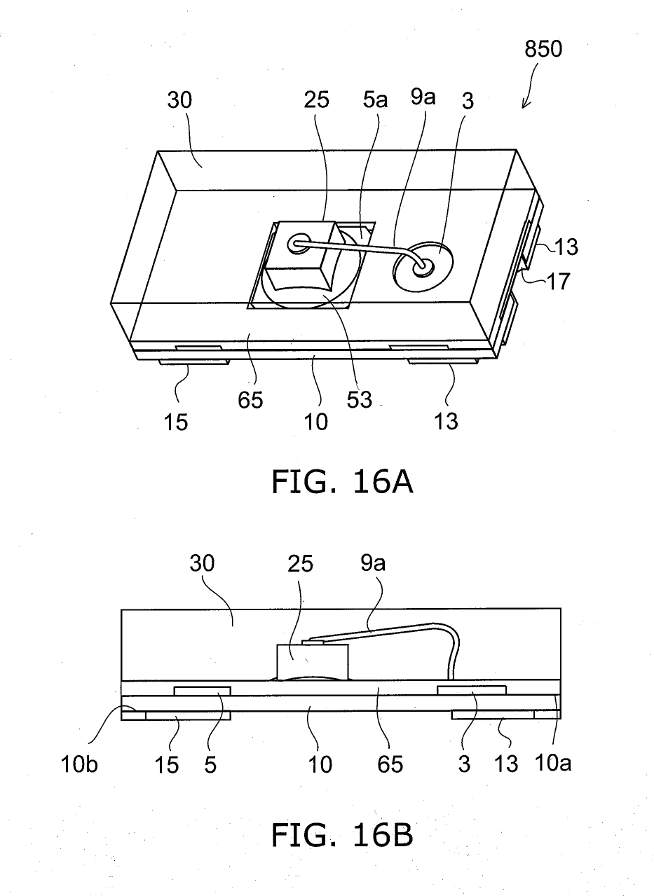

FIGS. 16A and 16B are schematic views illustrating a semiconductor light emitting device 850 according to a variation of the seventh embodiment. FIG. 16A is a perspective view schematically illustrating an external view of the semiconductor light emitting device 850, and FIG. 16B is a schematic front view thereof.

The semiconductor light emitting device 850 includes the insulating base 10, the semiconductor light emitting element 25, and resin 30 that seals the semiconductor light emitting element 25. The semiconductor light emitting element 25 emits light when current is passed between an upper surface electrode 25a and a lower surface electrode 25.

In the embodiment, a resin layer 65 is provided between the first face 10a of the base 10 and the resin 30 covering the large part of the first face 10a of the base 10, apart from a mounting portion of the semiconductor light emitting element 25 and a bonding portion of the metal wire 9a to the electrode 3. The resin layer 65 is a white resin that includes titanium oxide or the like, that reflects light emitted from the semiconductor light emitting element 25. Also, the electrical connections between the semiconductor light emitting element 25 and the base 10 are the same as those for the semiconductor light emitting device 800.

In the embodiment, adhesion is improved by interposing the resin layer 65 between the resin 30 and the base 10, so it is possible to suppress the penetration of solder or flux into the package. In addition, the brightness may be improved by the resin layer 65 reflecting the light emitted from the semiconductor light emitting element 25.

### Eighth Embodiment

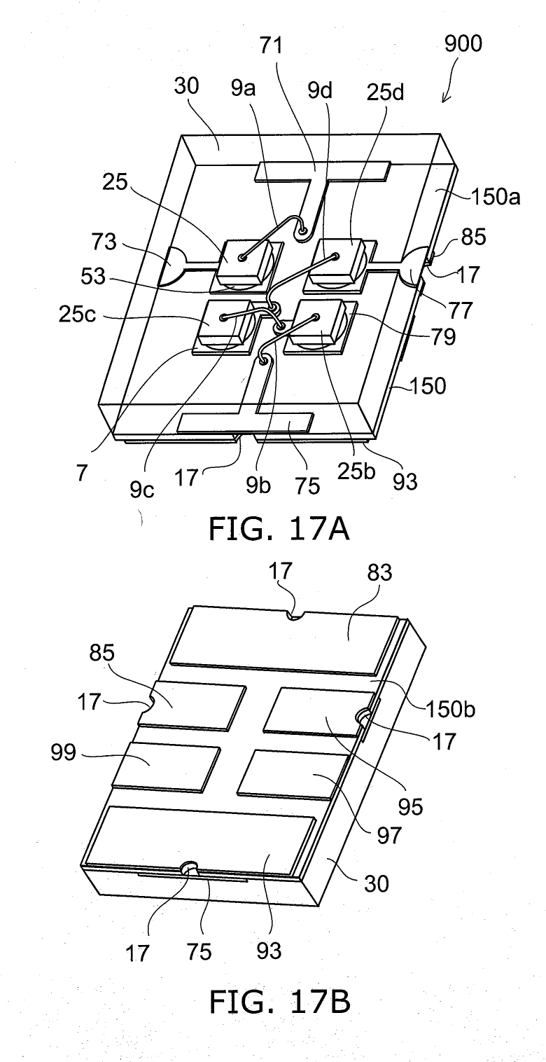

FIGS. 17A and 17B are schematic views of a semiconductor light emitting device 900 according to an eighth embodiment. FIG. 17A is a perspective view schematically illustrating an external view of a first face 150a side of a base 150, and FIG. 17B is a perspective view illustrating an external view of a second face 150b side.

As illustrated in FIG. 17A, four mount beds 79 are provided on the first face 150a, and semiconductor light emitting elements 25a, 25b, 25c, and 25d are fixed to the mount beds 79 using the electrically conductive paste 53. Also, four electrodes 71, 73, 75, 77 are provided on the first face 150a.

As illustrated in FIG. 17B, backside metal 83, 85, 93, 95, and 97 are provided on the second face 150b. The electrode 71 is electrically connected to the backside metal 83 via the recess portion 17 provided on a side face of the base 150. Also, the electrodes 73, 75, and 77 are electrically connected to the backside metal 85, 93, and 95 respectively via their respective recess portions 17.

An upper surface electrode of the semiconductor light emitting element 25a is connected to the electrode 71 via the metal wire 9a. On the other hand, a lower surface electrode of the semiconductor light emitting element 25a is connected to the electrode 73 via the mount bed 79, and is also connected to the backside metal 85 via the recess portion 17. Also, the semiconductor light emitting elements 25b, 25c, and 25d are connected in series between the electrode 75 and the electrode 77 via the metal wires 9b, 9c, and 9d.

For example, it is possible to control the light emitted from the semiconductor light emitting element 25a by controlling the current supplied between the backside metal 83 that is connected to the electrode 71, and the backside metal 85 that is connected to the electrode 73. Also, it is possible to control the light emitted from the semiconductor light emitting elements 25b, 25c, and 25d by controlling the current supplied between the backside metal 93 that is connected to the electrode 75, and the backside metal 95 that is connected to the electrode 77.

In this way, a plurality of semiconductor light emitting elements 25a to 25d is provided as desired, and the light emission of each may be controlled as desired via the backside metal 83, 85, 93, and 97.

As described above, the semiconductor light emitting device as illustrated in the first embodiment through the eighth embodiment can be manufactured by fixing a semiconductor light emitting element to a base, resin-sealing it, and cutting it using, for example, a dicing blade. In this way it is possible to reduce the manufacturing cost and increase the productivity. Also, it is possible to easily electrically connect an electrode provided on the first face and backside metal provided on the second face by forming the recess portion on a side face of the insulating base. In addition, a fillet can be easily formed when mounting the semiconductor light emitting device on the substrate, so it is possible to improve the reliability of the mounting. Also, it is possible to remove a device with a fault by melting a solder with heat providing through the fillet, and it is possible to repair the mounting substrate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting device, comprising:
a insulating base including a first face, a second face on a side opposite to the first face, and a side face connecting to the first face and the second face, a recess portion being provided on the side face extending from the first face to the second face, the insulating base including a first metal layer provided on the first face and blocking an opening of the recess portion, a second metal layer provided on an inner face of the recess portion, and a third metal layer provided on the second face, the third metal being electrically connected to the first metal layer via the second metal layer;
a semiconductor light emitting element fixed on the first face; and
resin covering the first face and sealing the semiconductor light emitting element, the resin transmitting at least part of light emitted from the semiconductor light emitting element.

2. The device according to claim 1, wherein the semiconductor light emitting element is electrically connected to the third metal layer via the first metal layer and the second metal layer.

3. The device according to claim 1, wherein the insulating base includes a through hole extending from the first face to the second face, and the semiconductor light emitting element is electrically connected to the third metal layer via the through hole.

4. The device according to claim 3, wherein the insulating base includes a fourth metal layer provided on the first face and blocking an aperture of the through hole, and a fifth metal layer provided on an inner face of the through hole, and the semiconductor light emitting element is electrically connected to the third metal layer via the fourth metal layer and the fifth metal layer.

5. The device according to claim 1, wherein the insulating base includes a through hole extending from the first face to the second face, and a sixth metal layer provided on the second face around the through hole, and the semiconductor light emitting element is electrically connected to the sixth metal layer via the through hole.

6. The device according to claim 5, wherein the base includes a fourth metal layer provided on the first face and blocking the aperture of the through hole, and a fifth metal layer provided on the inner face of the through hole, and the semiconductor light emitting element is electrically connected to the sixth metal layer via the fourth metal layer and the fifth metal layer.

7. The device according to claim 4, wherein the semiconductor light emitting element is fixed on the fourth metal layer.

8. The device according to claim 1, wherein the resin covers whole of the first face.

9. A semiconductor light emitting device, comprising:
a insulating base including a first face, a second face on a side opposite to the first face, and a side face connecting to the first face and the second face, a first recess portion being provided on the side face extending from the first face to the second face, the insulating base including a first outer electrode provided on the first face and blocking an opening of the first recess portion, a metal layer provided on an inner face of the first recess portion, and a first backside metal provided on the second face, the first backside metal being electrically connected to the first outer electrode via the metal layer of the first recess portion;
a semiconductor light emitting element fixed on the first face; and
a first resin covering the first face and sealing the semiconductor light emitting element transmitting at least part of light emitted from the semiconductor light emitting element.

10. The device according to claim 9, wherein the semiconductor light emitting element includes a first electrode electrically connected to the first outer electrode.

11. The device according to claim 10, wherein the insulating base includes a second recess portion provided on a different side face from the side face, a second outer electrode provided on the first face blocking an opening of the second recess portion, a metal layer provided on an inner face of the second recess portion, and a second backside metal provided on the second face and electrically connected to the second outer electrode via the metal layer of the second recess portion, and the semiconductor light emitting element includes a second electrode electrically connected to the second outer electrode.

12. The device according to claim 11, wherein the insulating base includes a first pad electrode connected to the first outer electrode, and a second pad electrode connected to the second outer electrode; and the first electrode of the semiconductor light emitting element is electrically connected to the first pad electrode via a metal wire, and the second electrode of the semiconductor light emitting element is electrically connected to the second pad electrode via a metal wire.

13. The device according to claim 11, wherein the semiconductor light emitting element is flip-chip bonded to a pair of electrodes connected to the first outer electrode and the second outer electrode respectively.

14. The device according to claim 11, further comprising a protective element fixed on the first face and connected in parallel with the semiconductor light emitting element between the first outer electrode and the second outer electrode.

15. The device according to claim 9, wherein
the insulating base includes a mount bed provided on the first face and blocking an aperture of a through hole extending from the first face to the second face, a metal layer provided on an inner face of the through hole, and a third backside metal provided on the second face and electrically connected to the mount bed via the metal layer; and
the semiconductor light emitting element is fixed on the mount bed.

16. The device according to claim 15, wherein the semiconductor light emitting element is electrically connected to the mount bed.

17. The device according to claim 16, wherein the semiconductor light emitting element includes a first electrode electrically connected to the first outer electrode.

18. The device according to claim 16, wherein
the insulating base includes a first pad electrode provided on the first face and blocking an aperture of another through hole different from the through hole, and a metal layer provided on an inner face of the another through hole and electrically connecting the first backside metal to the first pad electrode; and
the semiconductor light emitting element includes a first electrode electrically connected to the first pad electrode.

19. The device according to claim 9, further comprising a second resin provided on the first face along an outer edge of the insulating base and having a greater adhesion to the insulating base than the first resin.

20. The device according to claim 9, further comprising a third resin provided on the first face between the insulating base and the first resin except for a portion where the semiconductor light emitting element is fixed, the third resin reflecting light emitted from the semiconductor light emitting element.
